(19) United States
(12) Patent Application Publication
(10) Pub. No.: US 2005/0206277 A1
(43) Pub. Date: Sep. 22, 2005

(54) Tuning-fork-type vibrating reed, piezoelectric vibrator, angular-rate sensor, and electronic device

(75) Inventors: Makoto Eguchi, Suwa-shi (JP); Shigeo Kanna, Shimosuwa (JP); Masako Tanaka, Okaya-shi (JP)

Correspondence Address: OLIFF & BERRIDGE, PLC, P.O. BOX 19928, ALEXANDRIA, VA, 22320, US

(73) Assignee: Seiko Epson Corporation, Tokyo (JP)

(21) Appl. No.: 11/039,810

(22) Filed: Jan. 24, 2005

(30) Foreign Application Priority Data
Jan. 30, 2004 (JP) 2004-023935

(51) Int. Cl. H03H 9/15

(52) U.S. Cl. 310/370

(57) ABSTRACT

Exemplary embodiments provide a tuning-fork-type vibrating reed having satisfactory frequency-temperature characteristics in a broad temperature range, i.e. a tuning-fork-type vibrating reed exhibiting small changes in frequency over a broad temperature range is provided. The tuning-fork-type vibrating reed according to exemplary embodiments of the present invention includes a GaPO₄ piezoelectric material and a pair of arms having the thickness in Z′-axis direction, the width in X-axis direction, and the length in Y′-axis direction. The X-axis, the Y′-axis, and the Z′-axis are defined by rotating around the X-axis among the crystal X-axis, Y-axis, and Z-axis of the GaPO₄ by an angle between 7.7 degrees and 11.3 degrees measured clockwise as viewed from the origin looking in the positive X-axis direction.

### BACKGROUND

Exemplary embodiments of the present invention relate to tuning-fork-type vibrating reeds using gallium phosphate (GaPO₄) as piezoelectric material, piezoelectric vibrators, angular-rate sensors, and electronic devices.

The related art includes tuning-fork-type quartz resonators having tuning-fork-type quartz vibrating reeds that are used for vibrators to generate predetermined frequencies by bending vibration in clocks, electronic devices, and the like. The dependence of the frequency of a tuning-fork-type quartz resonator on temperature is small. For example, frequency-temperature characteristics (i.e. a change in frequency with a change in temperature) of a tuning-fork-type quartz resonator (not shown) are shown in FIG. 13. The tuning-fork-type quartz resonator is formed on a quartz substrate. In this tuning-fork-type quartz resonator, the X′-, Y′-, and Z′-axes are defined by rotating around the X-axis among the crystal X-, Y- and Z-axes of quartz by 1.5 degrees measured clockwise as viewed from the origin looking in the positive X-axis direction. The quartz substrate is cut perpendicular to the Z′-axis. The tuning-fork-type quartz resonator has a thickness in the Z′-axis direction, a width of an arm in the X′-axis direction, and a length of the arm in the Y′-axis direction. In FIG. 13, the horizontal axis represents temperature (° C.) and the vertical axis represents shift (ppm) of frequency from a reference frequency at 25° C.

In order to further reduce the change in frequency with the change in temperature, as disclosed in related art document Japanese Unexamined Patent Application Publication No. 54-40589, two vibrations generated by a tuning-fork-type quartz resonator are utilized for coupling two vibrations.

In another case as shown in related art document Japanese Unexamined Patent Application Publication No. 52-39391, two tuning-fork-type quartz vibrating reeds having different frequency-temperature characteristics, are mounted on a quartz substrate. In a tuning-fork-type quartz resonator using these tuning-fork-type quartz vibrating reeds, the difference in the two frequencies of the quartz vibrating reeds is used as a reference frequency.

Related art document (hereinafter “Delmas”), L. Delmas, F. Sthal, E. Bigler, B. Dulmet, and R. Bourquin, “Temperature-Compensated Cuts For Vibrating Beam Resonators Of Gallium Orthophosphate GaPO4” Proceedings of the 2003 IEEE International Frequency Control Symposium and PDA Exhibition, pp. 663-667, discloses that a GaPO₄ substrate can be used as an alternate of a quartz substrate.

However, in the tuning-fork-type quartz resonator disclosed in related art document Japanese Unexamined Patent Application Publication No. 54-40589, since the frequency-temperature characteristics significantly depend on the coupling level of the two vibrations, the productivity is low. Furthermore, the vibration readily leaks to a base. This results in a difficulty in supporting.

Since the tuning-fork-type quartz resonator disclosed in related art document Japanese Unexamined Patent Application Publication No. 52-39391 uses two tuning-fork-type quartz resonators, it has disadvantages of a high cost in addition to the difficulty in a reduction in size.

The resonator disclosed in Delmas has a simple vibrating beam reed. The calculation for the resonator having the vibrating beam reed is performed, but the calculation for the tuning-fork-type resonator having tuning-fork-type vibrating reeds is not performed. A theoretical formula used in the calculation takes only an elastic constant into account. Since a piezoelectric constant and a dielectric coefficient in a practical resonator are not taken into account, the calculation cannot define an optimized practical condition. In particular, GaPO₄ has a larger electromechanical coupling factor than that of quartz. Therefore, the optimum condition of a practical tuning-fork-type resonator having a piezoelectric constant and a dielectric coefficient is significantly different from the calculated value. As a result, desired frequency-temperature characteristics may not be addressed or achieved.

In order to overcome the above discussed and/or other problems described above, an object of exemplary embodiments of the present invention is to provide a tuning-fork-type vibrating reed having good frequency-temperature characteristics in a broad temperature range, i.e. to provide a tuning-fork-type vibrating reed, a piezoelectric vibrator, an angular-rate sensor, and an electronic device which exhibit small changes in frequency over a broad temperature range.

### SUMMARY

The inventors have investigated frequency-temperature characteristics of tuning-fork-type vibrating reeds prepared by cutting a GaPO₄ piezoelectric substrate at various angles, and have found that satisfactory frequency-temperature characteristics are addressed or achieved at a condition different from that disclosed in Delmas. Exemplary embodiments of the present invention have been completed based on this finding.

A tuning-fork-type vibrating reed according to exemplary embodiments of the present invention includes a GaPO₄ piezoelectric material and a pair of arms having the thickness in Z′-axis direction, the width in X-axis direction, and the length in Y′-axis direction. The X-axis, the Y′-axis, and the Z′-axis are defined by rotating around the X-axis among the crystal X-axis, Y-axis, and Z-axis of the GaPO₄ by an angle between 7.7° and 11.3° measured clockwise as viewed from the origin looking in the positive X-axis direction.

Preferably, the angle is between 8.4° and 10.7° measured clockwise as viewed from the origin looking in the positive X-axis direction.

A tuning-fork-type vibrating reed according to exemplary embodiments of the present invention includes a GaPO₄ piezoelectric material and a pair of arms having the thickness in Z′-axis direction, the width in X-axis direction, and the length in Y′-axis direction. The X-axis, the Y′-axis, and the Z′-axis are defined by rotating around the X-axis among the crystal X-axis, Y-axis, and Z-axis of the GaPO₄ by an angle between 52.9° and 54.4° measured clockwise as viewed from the origin looking in the positive X-axis direction.

A piezoelectric vibrator according to exemplary embodiments of the present invention includes the above-mentioned tuning-fork-type vibrating reed.

An angular-rate sensor according to exemplary embodiments of the present invention includes the above-mentioned tuning-fork-type vibrating reed.

An electronic device according to exemplary embodiments of the present invention includes the above-mentioned tuning-fork-type vibrating reed.

### BRIEF DESCRIPTION OF THE DRAWINGS

FIG. 1 is a schematic showing the crystal axes of GaPO₄;

FIG. 2 is a schematic showing a cutting angle of a piezoelectric substrate according to exemplary embodiments of the present invention;

FIG. 3(A) is a schematic showing a view from obliquely above the tuning-fork-type vibrating reed;

FIG. 3(B) is a schematic showing a view from obliquely below the tuning-fork-type vibrating reed;

FIG. 4 is a graph showing an example of the frequency-temperature characteristics in the tuning-fork-type vibrating reed according to a first exemplary embodiment of the present invention;

FIG. 5 is a graph showing the relationship between the angle θ and the peak temperature of the frequency-temperature characteristics in the tuning-fork-type vibrating reed according to the first exemplary embodiment of the present invention;

FIG. 6 is a graph showing the frequency-temperature characteristics of the tuning-fork-type vibrating reed according to a third exemplary embodiment of the present invention;

FIG. 7 is a graph showing the frequency variation of the tuning-fork-type vibrating reed according to a second exemplary embodiment in the temperature range of −40° C. to +120°;

FIG. 8 is a graph showing the frequency variation of the tuning-fork-type vibrating reed according to the third exemplary embodiment in the temperature range of −40° C. to +120° C.;

FIG. 9 is a schematic showing the entire structure of a cylindrical piezoelectric vibrator;

FIG. 10 is a schematic showing the entire structure of a chip-type piezoelectric vibrator;

FIG. 11 is a schematic showing the entire structure of an angular-rate sensor;

FIG. 12 is a schematic showing the actuation of the angular-rate sensor;

FIG. 13 is a graph showing an example of the frequency-temperature characteristics in a known tuning-fork-type quartz vibrating reed.

### DETAILED DESCRIPTION OF EMBODIMENTS

Exemplary embodiments of a tuning-fork-type resonator, a piezoelectric vibrator, an angular-rate sensor, and an electronic device according to exemplary embodiments of the present invention will be described with reference to the attached drawings.

### Exemplary Embodiments

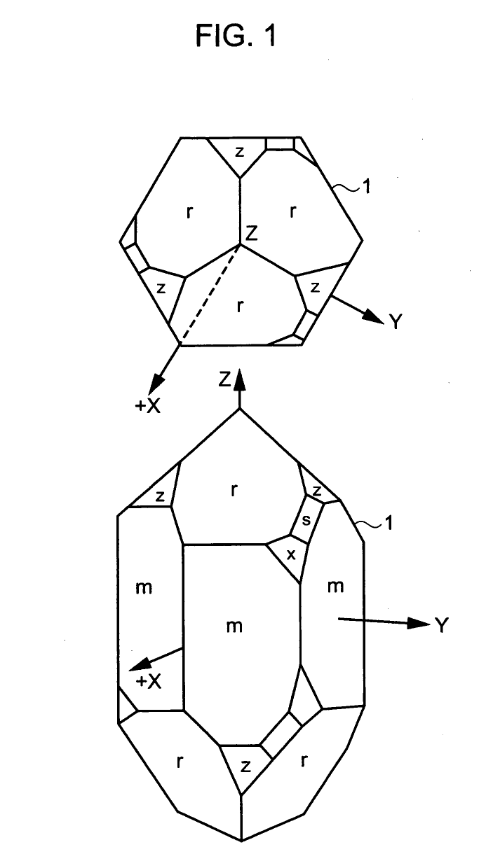

FIG. 1 is a schematic showing a definition of crystal axes of GaPO₄ to obtain a tuning-fork-type vibrating reed according to exemplary embodiments of the present invention. The crystal axes of crystal GaPO₄ 1 are defined by three orthogonal axes, X-, Y-, and Z-axes, as shown in FIG. 1.

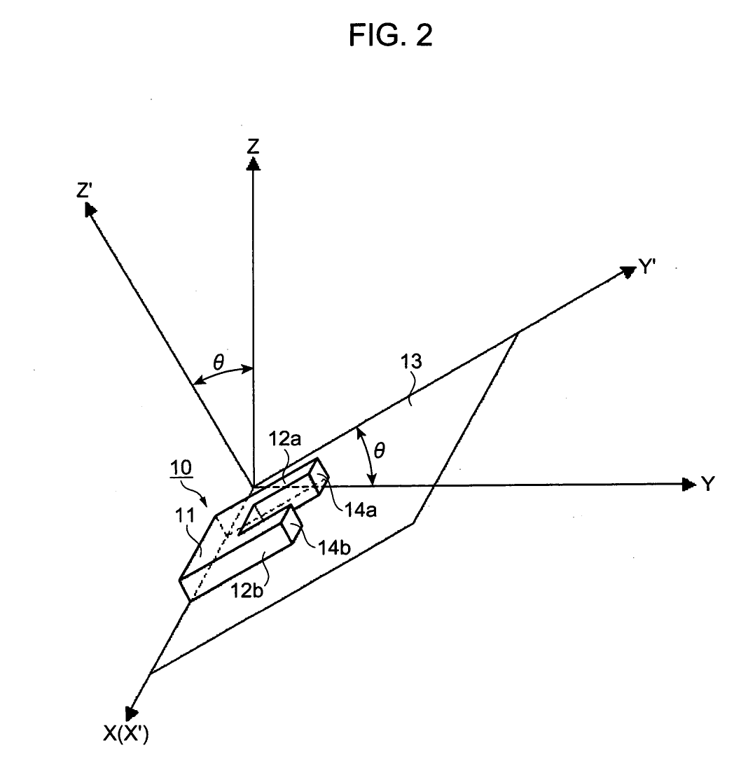

FIG. 2 is a schematic showing the relationship among the tuning-fork-type vibrating reed 10, crystal X-, Y-, and Z-axes, and a cutting angle of a piezoelectric substrate 13 according to exemplary embodiments of the present invention. New X′-, Y′-, and Z′-axes are defined by rotating around the X-axis among the crystal X-, Y-, and Z-axes of the crystal GaPO₄ 1 shown in FIG. 1 by an angle θ measured clockwise as viewed from the origin looking in the positive x-axis direction. The tuning-fork-type vibrating reed 10 according to exemplary embodiments of the present invention is mounted on the piezoelectric substrate 13 which is cut perpendicularly to the Z′-axis. Since the rotation is performed around the X-axis, the X′-axis is coincident with the X-axis. However, in order to clarify that the rotation is performed, X-axis after the rotation is defined as “X′-axis”. The X-axis after the rotation is referred to “X′-axis” in the best mode for carrying out exemplary embodiments of the invention.

The tuning-fork-type vibrating reed 10 is arranged on the piezoelectric substrate 13 so that the direction in which a pair of arms 12a and 12b line up, i.e. the width direction of arms 12a and 12b is the X′-axis; the thickness direction of the arms 12a and 12b is the Z′-axis; and the direction toward the ends 14a and 14b of the arms 12a and 12b, i.e. the longitudinal direction of the arms 12a and 12b is the Y′-axis.

The tuning-fork-type vibrating reed 10 has a substantially rectangular base 11 and two arms 12a and 12b extending in the Y′-axis direction. The arms 12a and 12b vibrate in flexure in opposite phase on the X′-Y′ plane. In FIG. 2, the arms 12a and 12b extend along the positive direction of the Y′-axis, but they can extend along the negative direction of the Y′-axis in the Y-axis. Namely, the addition of 180° to the angle θ results in the same relationship among the tuning-fork-type vibrating reed 10, the crystal X-, Y-, and Z-axes, and the cutting angle of the piezoelectric substrate 13 as that described based on FIG. 2.

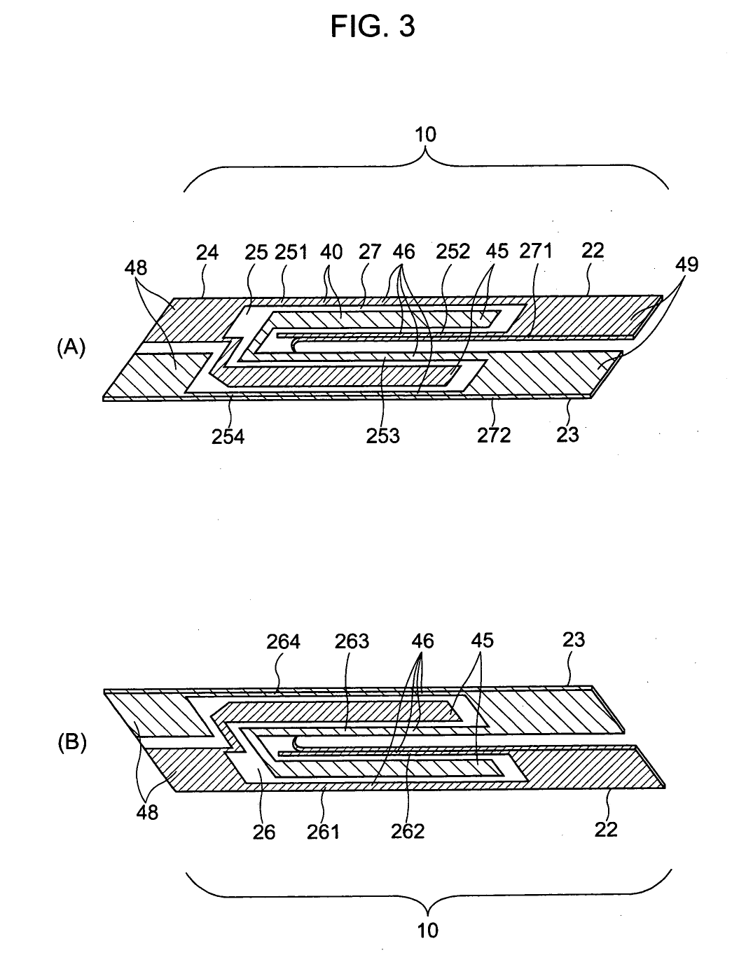

Next, an example of electrode of the tuning-fork-type vibrating reed 10 will be described. FIGS. 3(A) and (B) are schematics showing the tuning-fork-type vibrating reed. FIG. 3(A) is a schematic showing from obliquely above and FIG. 3(B) is a schematic showing from obliquely below.

As shown in FIGS. 3(A) and (B), driving electrodes 45 having two electrode patterns 40 at a predetermined distance of a gap 27 are formed in the centers on the top face 25 and bottom face 26 of the arms 22 and 23 of the tuning-fork-type vibrating reed 10. In FIGS. 3(A) and (B), in order to distinguish the two electrode patterns 40 from each other, one electrode pattern 40 is illustrated with lines sloping downward to the right and the other electrode pattern 40 is illustrated with lines sloping upward to the right.

The driving electrodes 45 are disposed in the centers on the top face 25 and bottom face 26 of the arms 22 and 23 of the tuning-fork-type vibrating reed 10. The driving electrodes 45 on the top face 25 and the driving electrodes 45 on the bottom face 26 are electrically connected by conducting electrodes 46 having electrode patterns 40 disposed at edges 251, 252, 253, and 254 of the top face 25, margins 261, 262, 263, and 264 of the bottom face 26, and edges 271 and 272.

On the base 24, the electrode patterns 40 are used as supporting electrodes 48 (or referred to mounting portions) and are electrically connected to joint terminals (not shown) with solder or a conductive adhesive. In such a state, when an AC voltage is applied to the driving electrodes 45 via the joint terminals, the arms 22 and 23 vibrate at a predetermined frequency. In this case, the conducting electrodes 46 excite the tuning-fork-type vibrating reed 10. Furthermore, weights 49 for frequency adjustment are provided at end portions of the arms 22 and 23 by laser trimming or the like.

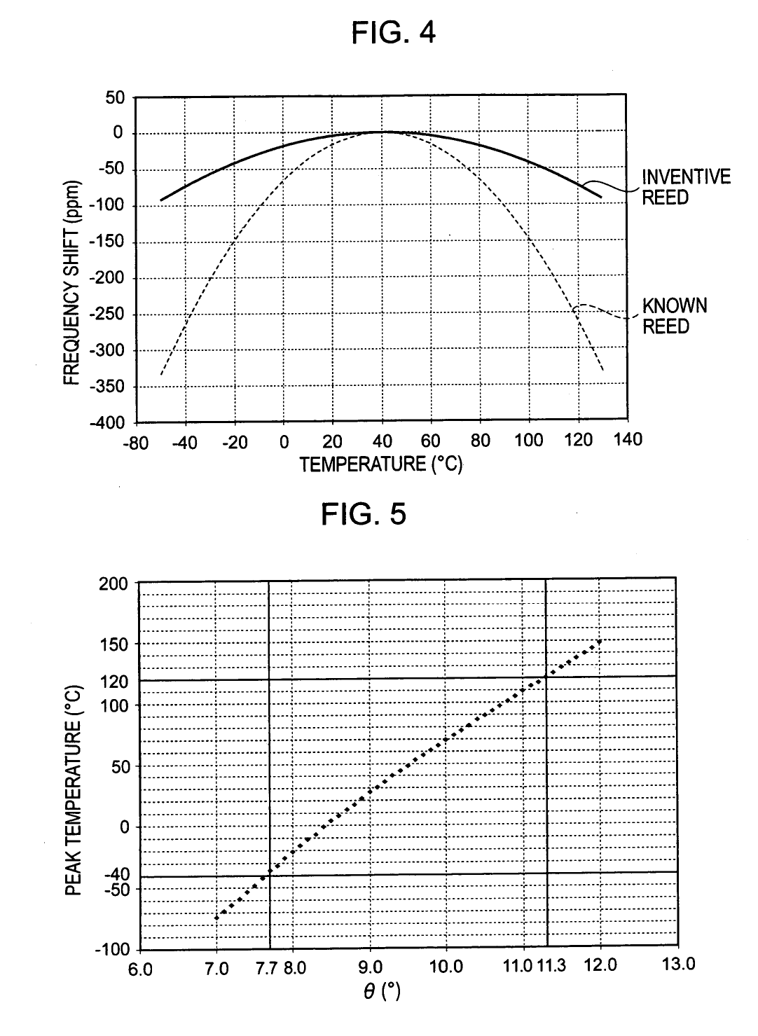

FIG. 4 is a graph showing frequency-temperature characteristics of a known tuning-fork-type quartz vibrating reed and a tuning-fork-type vibrating reed (angle θ=9.3°) according to a first exemplary embodiment of the present invention. As shown in FIG. 4, in the tuning-fork-type vibrating reed having a rotating angle θ of 9.3° according to exemplary embodiments of the present invention, the shift of the frequency from the maximum frequency used as a reference in the temperature range of −40° C. to +120° C. [(frequency variation)=(maximum frequency shift)−(minimum frequency shift)] is small compared with that of the related art tuning-fork-type quartz vibrating reed.

FIG. 5 is a graph showing a relationship between the rotating angle θ of the tuning-fork-type vibrating reed according to the first exemplary embodiment of the present invention and a peak temperature of the frequency-temperature characteristics. The peak temperature is defined as a temperature when the frequency-temperature characteristics exhibit a inflection point, for example, a temperature when the maximum frequency is observed in FIG. 4. As shown in FIG. 5, in the range of angle θ of 7.7° to 11.3°, the peak temperature ranges from −40° C. to +120° C. The temperature range of consumers' use (referred to service temperature range hereinafter) is between −40° C. and +120° C. at the broadest. A temperature at which a tuning-fork-type vibrating reed is generally used depends on the purpose, so it is desired that the tuning-fork-type vibrating reed have a peak temperature close to the temperature at which it is generally used. Therefore, when the angle θ is between 7.7° and 11.3°, the tuning-fork-type vibrating reed can have a peak temperature close to the temperature at which it is generally used. As shown in FIG. 4, a frequency variation per unit temperature is small at a temperature close to the peak temperature. Consequently, a tuning-fork-type vibrating reed exhibiting a reduced change in frequency with a change in temperature and having stable frequency-temperature characteristics can be provided.

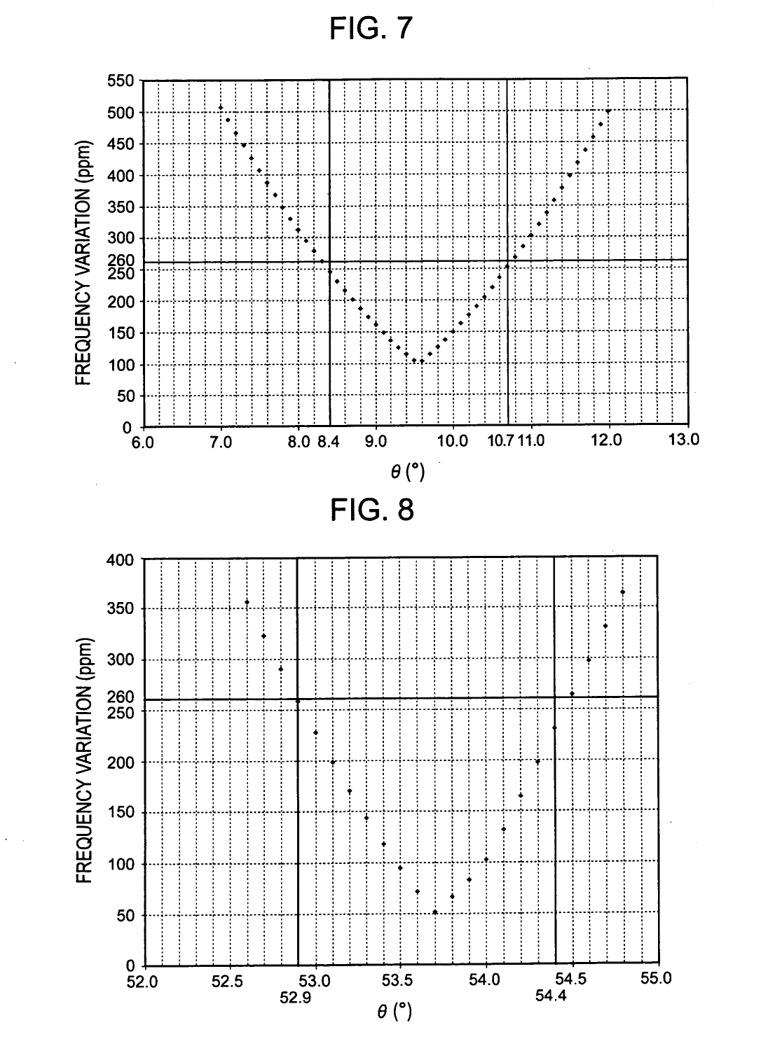

FIG. 7 is a graph showing a frequency variation of a tuning-fork-type vibrating reed according to a second exemplary embodiment of the present invention in the temperature range of −40° C. to +120° C. As shown in FIG. 7, when the angle θ is in the range of 8.40 to 10.70, the tuning-fork-type vibrating reed according to the second exemplary embodiment exhibits a frequency variation of about 260 ppm or less. The related art tuning-fork-type quartz vibrating reed shown in FIG. 4 exhibits a frequency variation of about 260 ppm in the temperature range of −40° C. to +120° C. Namely, the frequency variation of a piezoelectric vibrating reed according to exemplary embodiments of the present invention is smaller than that of the related art tuning-fork-type quartz vibrating reed in the temperature range of −40° C. to +120° C., i.e. the frequency variation can be reduced. For example, at an angle θ of 9.6°, a frequency variation of about 100 ppm can be addressed or achieved. Such a frequency variation is significantly smaller than that of the related art tuning-fork-type quartz vibrating reed.

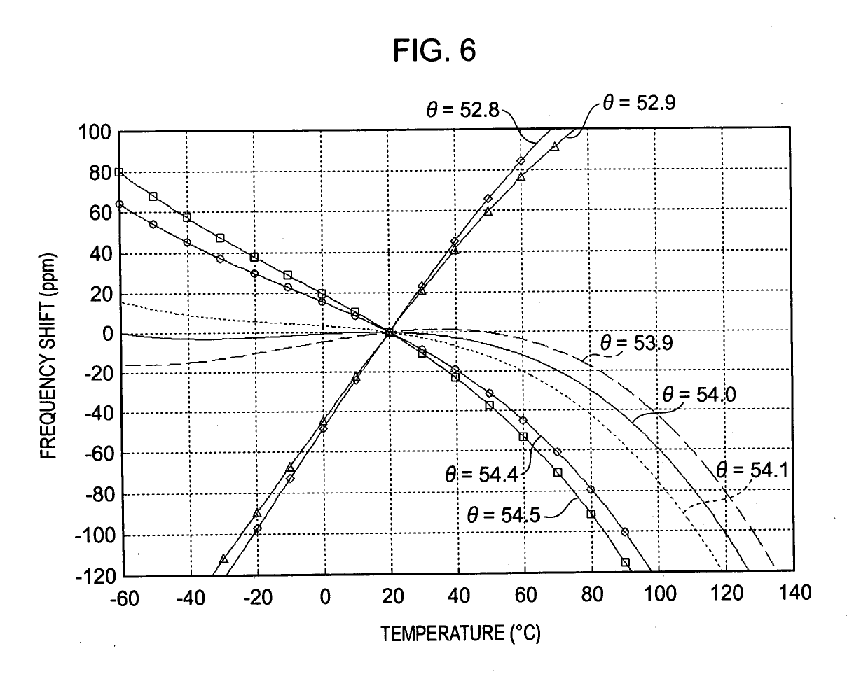

FIG. 6 is a graph showing frequency-temperature characteristics of a tuning-fork-type vibrating reed according to a third exemplary embodiment of the present invention. As shown in FIG. 6, at an angle θ close to 54.0°, the tuning-fork-type vibrating reed according to the third exemplary embodiment has frequency-temperature characteristics showing a cubic curve and exhibits a small change in frequency with a change in temperature. Thus, the tuning-fork-type vibrating reed has a stable frequency. In particular, at a temperature close to a room temperature, the curve of the frequency-temperature characteristics is almost parallel to the horizontal axis of the graph and the shift in frequency can be particularly reduced.

FIG. 8 is a graph showing a frequency variation of the tuning-fork-type vibrating reed according to the third exemplary embodiment of the present invention in the temperature range of −40° C. to +120° C. As shown in FIG. 8, at an angle θ in the range of 52.9° to 54.4°, the frequency variation is about 260 ppm or less. Namely, the tuning-fork-type vibrating reed according to the third exemplary embodiment has a small change in frequency at a temperature in the range of −40° C. to +120° C. compared with that of a known tuning-fork-type quartz vibrating reed.

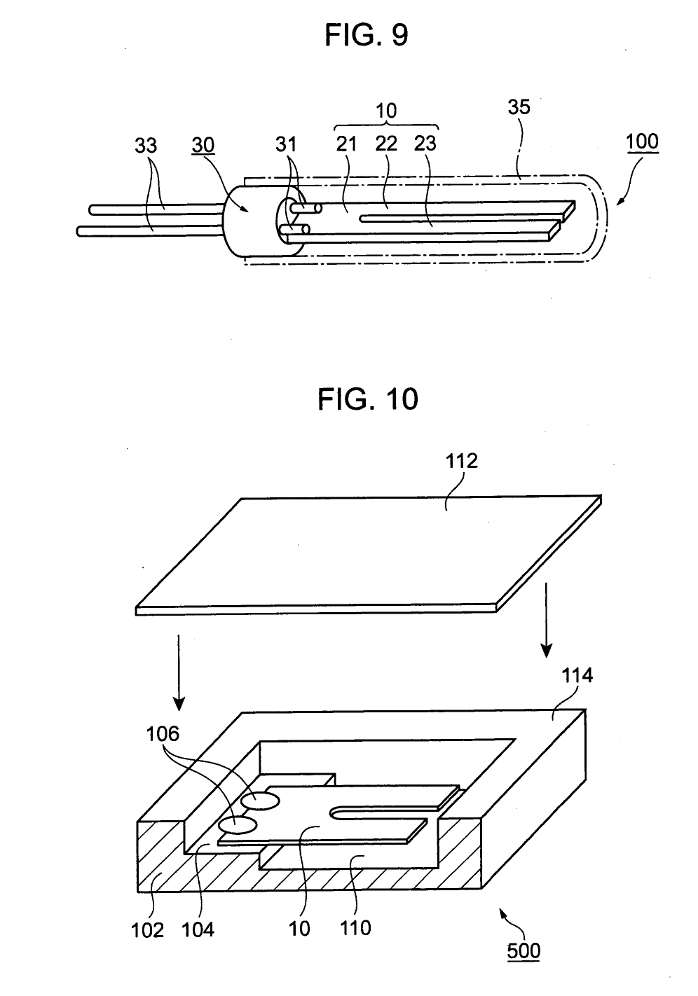

A piezoelectric vibrator using a tuning-fork-type vibrating reed according to exemplary embodiments of the present invention will now be described with reference to FIGS. 9 and 10. FIG. 9 is a schematic showing the entire structure of a cylindrical piezoelectric vibrator having a cylindrical shape as an example of the piezoelectric vibrator. FIG. 10 is a schematic showing the entire structure of a chip-type piezoelectric vibrator having a rectangular parallelepiped shape as another example of the piezoelectric vibrator.

The cylindrical piezoelectric vibrator will now be described. As shown in FIG. 9, the cylindrical piezoelectric vibrator 100 includes a tuning-fork-type vibrating reed 10 including a thin tabular piezoelectric substrate (GaPO₄) having a pair of arms 22 and 23 extending from a base 21, a plug 30 having internal terminals 31 connecting to the base 21 of the tuning-fork-type vibrating reed 10, and a case 35 for storing the tuning-fork-type vibrating reed 10. The internal terminals 31 pass through the plug 30 to external terminals 33.

The tuning-fork-type vibrating reed 10 is connected to the internal terminals 31 at the end of the base 21 with a bonding material (not shown) such as solder. The plug 30 having the internal terminals 31 connected to the tuning-fork-type vibrating reed 10 is pressed into the case 35 to maintain the air tightness.

Next, the chip-type piezoelectric vibrator will be described. As shown in FIG. 10, in the chip-type piezoelectric vibrator 500, a tuning-fork-type vibrating reed 10 is connected to a base table 104 in a storage container 102 made of, for example, ceramic with a conductive adhesive 106 or the like. The structure having the base table 104 reduces or prevents contact of the vibrating portions of the tuning-fork-type vibrating reed 10 with the bottom face 110 of the storage container 102. A cover 112 is joined with a joining portion 114 of the storage container 102 storing the tuning-fork-type vibrating reed 10. The joining of the cover 112 maintains the air tightness in the storage container 102.

In the cylindrical piezoelectric vibrator 100 and chip-type piezoelectric vibrator 500 according to one of the exemplary embodiments, since the tuning-fork-type vibrating reed 10 described in the above-mentioned exemplary embodiments is used, the piezoelectric vibrators have the same effects as those of the tuning-fork-type vibrating reed. In particular, a piezoelectric vibrator which can reduce the shift of the frequency from the maximum frequency used as a reference in the temperature range of −40° C. to +120° C. [(frequency variation)=(maximum frequency shift)−(minimum frequency shift)] can be provided.

In the above description on the structure of the piezoelectric vibrator 100 and the chip-type piezoelectric vibrator 500, the tuning-fork-type vibrating reed 10 is stored in the case 35 or the storage container 102. The case 35 and the storage container 102 can additionally store at least a circuit component (not shown) such as a circuit element that drives the tuning-fork-type vibrating reed 10 for providing a piezoelectric oscillator.

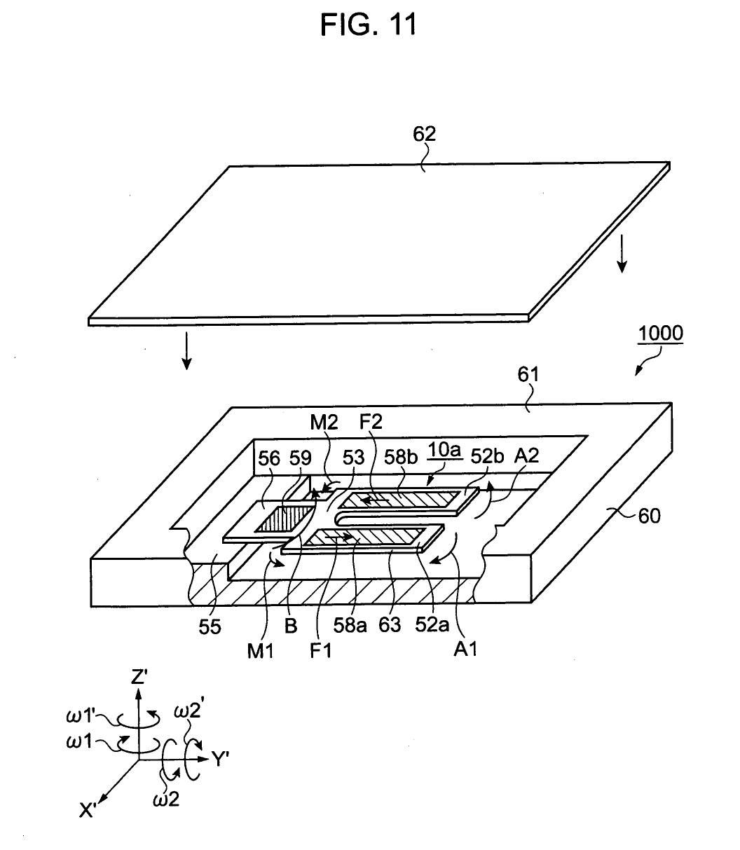

Next, an example of an angular-rate sensor using a tuning-fork-type vibrating reed according to exemplary embodiments of the present invention will be described with reference to the attached drawing. FIG. 11 is a schematic showing a partial cross section of a perspective view from obliquely above to show the entire structure of an angular-rate sensor.

As shown in FIG. 11, an angular-rate sensor 1000 includes a tuning-fork-type vibrating reed 10a that is formed according to one of the exemplary embodiments described above as a dedicated element for the angular-rate sensor 1000. The angular-rate sensor 1000 utilizes a Coriolis force generated by applying an angular rate of rotation to a vibrating material. The distortion due to a change in shape with the Coriolis force is extracted as an electric signal to detect the angular rate.

A structure of the angular-rate sensor will now be described. As shown in FIG. 11, the angular-rate sensor 1000 includes a piezoelectric vibrating reed 10a, a storage container (package) 60 made of, for example, ceramic to store the piezoelectric vibrating reed 10a, and a cover 62 for sealing the opening of the storage container 60. The piezoelectric vibrating reed 10a is made of a thin tabular piezoelectric substrate (GaPO₄). The piezoelectric vibrating reed 10a is composed of a pair of arms 52a and 52b and a supporting portion 56. The arms 52a and 52b are connected to each other via a base 53 on the X′-Y′ plane. The supporting portion 56 extends from the base 53 to mount the piezoelectric vibrating reed 10a on a fixing portion 55 of the storage container 60. Excitation electrodes 58a and 58b are disposed on the surfaces of the arms 52a and 52b, and a detection electrode 59 is disposed on the surface of the supporting portion 56. The end of the supporting portion 56 of the piezoelectric vibrating reed 10a is fixed to the fixing portion 55 of the storage container 60 with a conductive adhesive (not shown) or the like. The cover 62 is joined to the top face 61 of the storage container 60 to maintain the air tightness.

Next, the operation of the angular-rate sensor will be described. In a rotation system around Z′-axis (central axis), the arms 52a and 52b are vibrated by the excitation electrodes 58a and 58b so as to each have a completely opposite phase in the X′-Y′ plane (shown as A1 and A2). In this state, when an angular rate of rotation ω1 is applied around the Z′-axis, forces F1 and F2 work on the arms 52a and 52b, respectively, in the opposite directions along the Y′-axis due to the Coriolis force. As a result, momenta M1 and M2 work at both the ends of the base 53. The momenta M1 and M2 generate bending vibration B in the X′-Y′ plane at the supporting portion 56. The angular rate of rotation c 1 is measured by detecting the bending vibration B by the detection electrode 59. The angular rate of rotation can be also measured by detecting the angular rate of rotation ω1′ in the counter direction of the angular rate of rotation ω1.

When the tuning-fork-type vibrating reed 10a shows an unstable frequency, both the driving vibration frequency and the detected vibration frequency of the tuning-fork-type vibrating reed change with a change in temperature. As a result, the detection sensitivity changes. In other words, the detection sensitivity depends on a change in difference between the driving vibration frequency and the detected vibration frequency. Due to such a change in detection sensitivity, an electric signal (referred to leakage output) as if a Coriolis force worked on may be detected despite that an angular rate of rotation is not applied. However, since the angular-rate sensor according to the exemplary embodiment has stability of frequency to temperature, a change in the leakage output with the change in temperature can be decreased. It is known that the electromechanical coupling coefficient of GaPO₄ is larger than that of quartz. Therefore, the electric signal output from an elemental substance can be increased and the load on an amplifier in a detection circuit can be reduced.

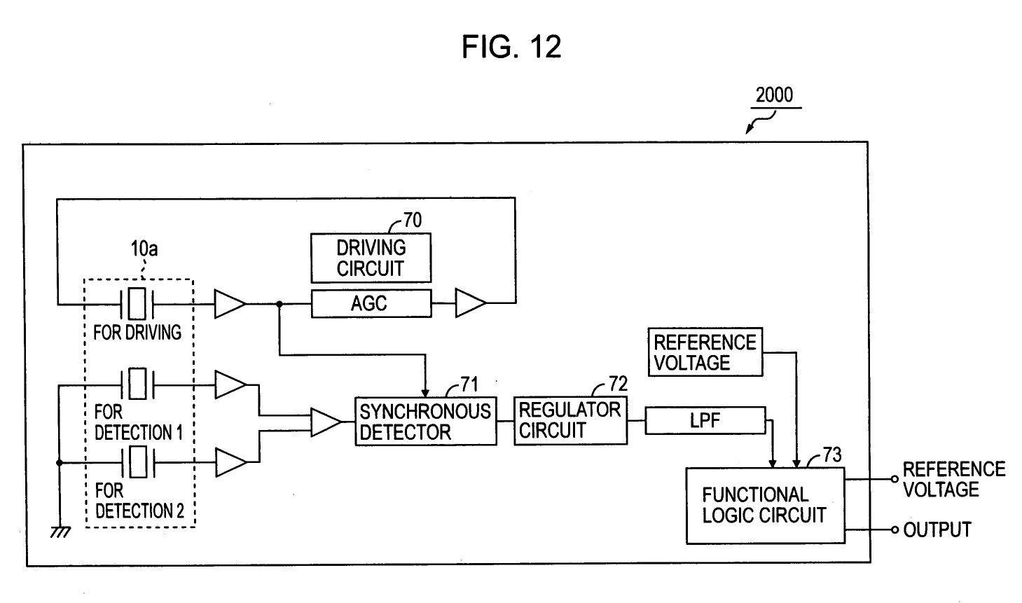

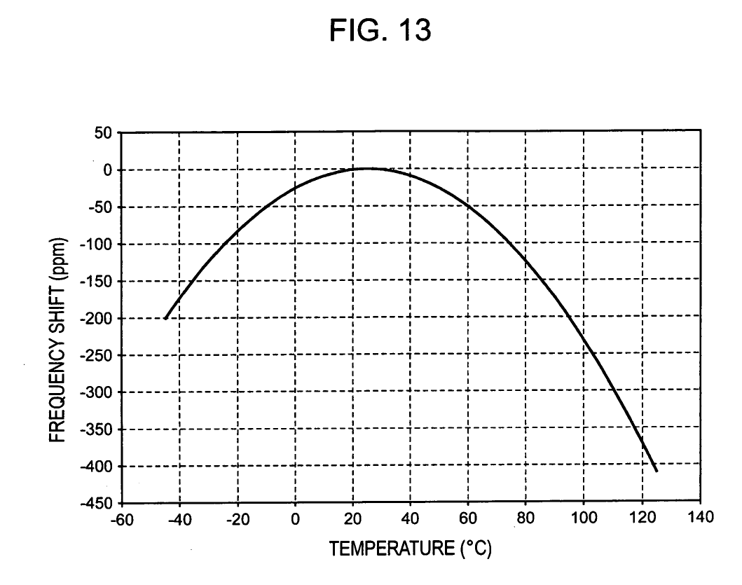

In the above description on the angular-rate sensor 1000, only the tuning-fork-type vibrating reed 10a is stored in the storage container. However, circuit components can be also stored in this storage container to provide a circuit integrated angular-rate sensor. As shown in a circuit block diagram of the circuit integrated angular-rate sensor 2000 in FIG. 12, the tuning-fork-type vibrating reed 10a and circuit components such as a driving circuit 70 for driving the tuning-fork-type vibrating reed 10a, a synchronous detector 71 to process a detected electric signal derived from an angular rate, a regulator circuit 72, and a functional logic circuit 73, are stored in one storage container. However, the storage container may not store all these blocks shown in FIG. 12. For example, the storage container may store only the tuning-fork-type vibrating reed 10a and the driving circuit 70.

In the above description on the angular-rate sensor 1000, the angular rate of rotation ω1 is applied around the Z′-axis. However, the angular rate of rotation around another axis may be detected. For example, by forming detection electrodes (not shown) at the side faces 63 of the arms 52a and 52b of the tuning-fork-type vibrating reed 10a shown in FIG. 11, the angular rate of rotation ω2 around the Y′-axis or the angular rate of rotation ω2′ in the counter direction of the angular rate of rotation ω2 can be detected.

Furthermore, electronic devices having tuning-fork-type vibrating reeds according to the exemplary embodiment include oscillators generating reference frequencies, mobile phones, and digital cameras. Each electronic device can generate a stabilized frequency without a temperature-compensating circuit even if the electronic device provided with the tuning-fork-type vibrating reed according to the above-mentioned exemplary embodiment is used in a broad temperature range. Therefore, an increase in the number of components of the circuit can be avoided and a process is simplified. Consequently, the manufacturing cost is reduced. Furthermore, the frequency variation caused by the allowance range in the manufacturing process, not the change in frequency with a change in temperature, can also readily modified by peripheral circuits because of the high electromechanical coupling coefficient.

As described above, according to exemplary embodiments of the present invention, a tuning-fork-type vibrating reed having stable frequency-temperature characteristics can be provided by using a GaPO₄ substrate cut at a particular angle. Therefore, a small sized tuning-fork-type vibrating reed having stable frequency-temperature characteristics can be readily provided without complicated mode coupling or a plurality of vibrating reeds.

1. A tuning-fork-type vibrating reed, comprising:
a GaPO₄ piezoelectric material; and
a pair of arms having a thickness in a Z′-axis direction, a width in an X-axis direction, and a length in a Y′-axis direction, the X-axis, the Y′-axis, and the Z′-axis being defined by rotating around the X-axis among a crystal X-axis, Y-axis, and Z-axis of the GaPO₄ by an angle between 7.7 degrees and 11.3 degrees measured clockwise as viewed from an origin looking in a positive X-axis direction.

2. The tuning-fork-type vibrating reed according to claim 1, the angle being between 8.4 degrees and 10.7 degrees measured clockwise as viewed from the origin looking in the positive X-axis direction.

3. A tuning-fork-type vibrating reed, comprising:
a GaPO₄ piezoelectric material; and
a pair of arms having a thickness in a Z′-axis direction, a width in an X-axis direction, and a length in a Y′-axis direction, the X-axis, the Y′-axis, and the Z′-axis being defined by rotating around the X-axis among a crystal X-axis, Y-axis, and Z-axis of the GaPO₄ by an angle between 52.9 degrees and 54.4 degrees measured clockwise as viewed from an origin looking in a positive X-axis direction.

4. A piezoelectric vibrator, comprising:
a tuning-fork-type vibrating reed according to claim 1.

5. An angular-rate sensor, comprising:
a tuning-fork-type vibrating reed according to claim 1.

6. An electronic device, comprising:
a tuning-fork-type vibrating reed according to claim 1.
